(19) United States
(12) Patent Application Publication
(10) Pub. No.: US 2006/0172065 A1
(43) Pub. Date: Aug. 3, 2006

(54) Vacuum deposition of coating materials on powders

(76) Inventor: John A. Carlotto, Barrington, RI (US)

Correspondence Address: SALTER & MICHAELSON;THE HERITAGE BUILDING, 321 SOUTH MAIN STREET, PROVIDENCE, RI, 029037128, US

(21) Appl. No.: 11/343,686

(22) Filed: Jan. 31, 2006

Related U.S. Application Data
(60) Provisional application No. 60/648,767, filed on Feb. 1, 2005.

(51) Int. Cl. C23C 16/00; B05D 7/00; H05H 1/24

(52) U.S. Cl. 427/212; 427/569; 427/248.1; 118/726; 118/719

(57) ABSTRACT

A powder material moved and mixed by the application of a mechanical force. The moving of the bed of powder in a container while the container is in a vacuum under a vapor source produced by magnetron sputtering, thermal evaporation, or other means of producing a coating vapor such as plasma enhanced chemical vapor deposition (PECVD), provides a means of coating the particles of powder with a material which will impart certain other desirable characteristics to the base material of which the powder is composed. The range of and combinations of coatings include a pure metal, co-deposited metals, and non-metals formed by reactive magnetron sputtering, evaporation or PECVD, or a sequentially deposited coating of both metals and non-metals. The mechanical means may be by striking, stirring or a piezoelectric transducer may be used. The mechanical force may be imposed on an open moving container of the bulk material in a vacuum or an open stationary container of the bulk material in a vacuum.

### RELATED APPLICATIONS

The present application claims priority to U.S. Provisional Application Ser. No. 60/648,767 filed on Feb. 1, 2005.

### TECHNICAL FIELD

The present invention relates in general to a method of vacuum depositing a coating or coatings on a particulate material. More particularly, the present invention pertains to a method and apparatus for the moving of materials in bulk, such as powders, by the application of a mechanical force on container(s) for the powder while moving under a physical vapor deposition source. The present invention also relates to coated materials and to uses therefore.

### BACKGROUND OF THE INVENTION

Prior to the present invention there has been no practical means available for coating of individual particles of a powdery substance, particularly in the nanometer particle size range, and more particularly, in multiple moving open containers and in bulk. Also, there is no existing technique for the coating of particles of a powdery substance with multiple coatings of metals and compounds, in multiple moving containers at low temperature with a vapor produced by means of magnetron sputtering, reactive magnetron sputtering or thermal evaporation.

There are existing patents relating to the coating of fine powders by sputtering with a high frequency source on a dispersion of particles moving through a vapor zone. Refer to U.S. Pat. No. 4,940,523. Other patents refer to metal sputter coating substrates in a caged container. See for example, U.S. Pat. No. 4,080,281 and U.S. Pat. No. 5,755,937. Refer also to U.S. Pat. No. 4,440,800 which describes a method for coating powders by electrostatic material handling and the use of a vapor source. Other patents describe methods of moving particles under a magnetron sputtering source and in a vapor stream but use a stationary container. Refer to U.S. Pat. Nos. 6,241,858; 6,355,146 and 6,149,785.

Accordingly, it is an object of the present invention to provide a technique for the coating of individual particles of a powdery substance, particularly in the millimeter to nanometer particle size range.

A further object of the present invention is to provide a coating method using mechanical means in an open container and which is well adapted for particulate coating in bulk.

Still another object of the present invention is to provide a method of moving a powdery substance by mechanical means within a moving container or a stationary container with a magnetron sputtering source or a thermal evaporative source.

A further object of the present invention is to provide a method of surface coating of particles in the nanometer to submillimeter size.

Still a further object of the present invention is to provide a method of surface coating of particles with multiple layers of metallic or compound materials.

### SUMMARY OF THE INVENTION

In accordance with one aspect of the present invention there is provided a method of vapor coating of a particulate material that includes the step of moving the particulate material by mechanical means and causing the movement of particulate material so that all surfaces of the particle will, in time, interact with a vapor of a coating material. The present invention relates to the moving of materials in bulk, such as powders, by the application of such a mechanical force. This mechanical force can be applied either to an open moving container of the bulk material in a vacuum or an open stationary container of the bulk material in a vacuum. The invention also relates to a method of vacuum coating, with single or multiple coatings, of such materials in the bulk container. The invention also relates to coated materials and to uses therefore. The invention also relates to the coating of particulate material of sub-millimeter size. Sub-millimeter refers to particle sizes of one millimeter diameter or less.

In accordance with other features of the present invention the vapor coating may be conducted under vacuum with the vapor of a coating material being supplied from a source internal to a vacuum chamber; the moving of the particulate material and generation of the vapor of a coating material are conducted in a single vacuum chamber with a single or several open containers holding up to 50 grams each of the particulate material of the same or different compositions; the open container holding the particulate material may be rotated under the vapor source in a sequential or random fashion; the method may be carried out under conditions of a vacuum in the 0.1 to 0.0005 torr range with an energized inert gas as a plasma to create the vapor; carried out at a temperature of less than 160 degrees F.; carried out under conditions of a vacuum in the 0.0005 to 0.000001 torr range with a thermal source providing the means of producing the vapor; a compound coating is created by a gas that reacts with the vapor created by the energized inert gas plasma striking a charged electrode; the coating material may be vaporized from an electrode at high negative potential above an open container with a moving bed of the particulate material in a vacuum in the range 0.1 to 0.0005 torr; the coating material may be vaporized from an electrode which is at negative potential with respect to ground and the material being coated is at ground potential, or positive potential or negative potential with respect to ground; the thickness of the coating of the vapor-coated material is controlled by varying the rate of production of said vapor-coating material; the moving of the particulate material may be by striking the container for the particulate material or the moving of the particulate material may be by stirring the material in the container for the particulate material.

In accordance with another aspect of the present invention there is provided a method of preparing discrete coated particles having:
(i) an inner core of a first material which is capable of being moved by a mechanical means.
(ii) an outer coating of a second material which is capable of being vaporized.
   The method comprises:
(a) moving particles of the first material by the application of a mechanical force; and
(b) vaporizing of and subsequently depositing the second material as a vapor onto the surface of the particles of the first material.

Subsequent coatings of the same material or other materials can be added according to the preceding scheme by incorporating sufficient magnetron sputtering electrodes and charging them sequentially or simultaneously. In accordance with a further aspect of the present invention there is provided an apparatus for coating particulate material in a vacuum chamber, comprising: a container for the particulate material; means for supporting the container in the chamber; means for mechanically agitating the particulate material within the container; and electrode means for establishing a coating vapor within the vacuum chamber. The apparatus may further include a platform for the container, including a plurality of containers on the platform, with the mechanical means including a strike rod engaging with the container for mechanically moving the particulate material. In another embodiment the mechanical means may include a stirring paddle or piezoelectric transducer for stirring the particulate material in the container, and the container may be maintained moving or stationary.

### DESCRIPTION OF THE DRAWINGS

Numerous other objects, features and advantages of the present invention should now become apparent upon a reading of the following detailed description, when taken in conjunction with the following drawings, in which:

FIG. 1 is a schematic diagram of an apparatus used in accordance with the method of the present invention for vacuum deposition of coating materials;

FIG. 2 is a schematic diagram of an alternate apparatus used in accordance with the method of the present invention for vacuum deposition of coating materials;

FIG. 3 is a cross-sectional view of the first embodiment taken along line 3-3 of FIG. 1; and

FIG. 4 is a fragmentary view of a further alternate embodiment using a piezo-electric transducer.

### DETAILED DESCRIPTION

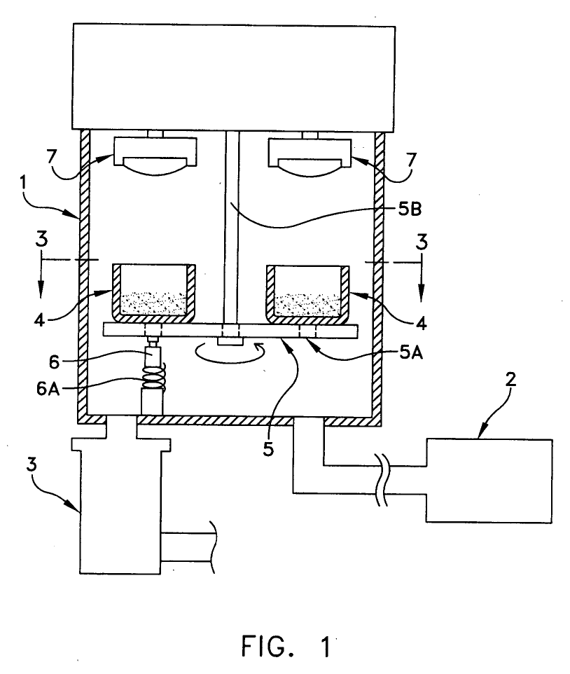

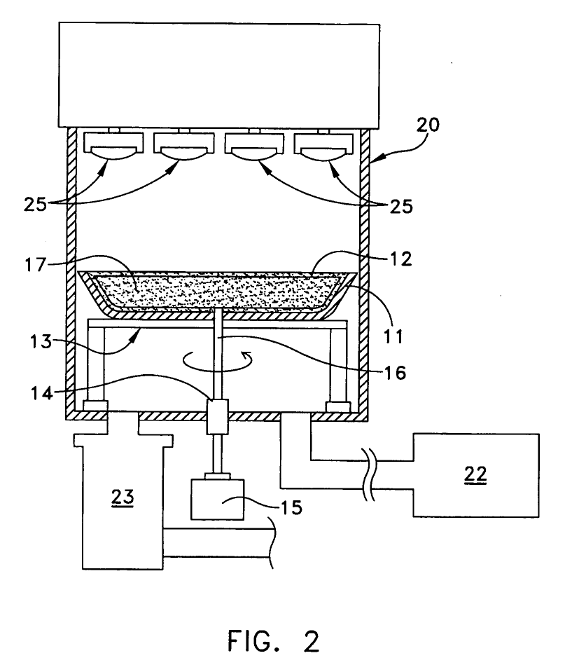

Reference is first made to FIGS. 1 and 2 for schematic diagrams of two different apparatus that may be used in the practice of the present invention. Both of these embodiments illustrate the moving of materials such as powders, in bulk, by the application of a mechanical force on either an open moving container of the bulk material in a vacuum or an open stationary container of the bulk material in a vacuum. The apparatus practices a method of vacuum coating, with single or multiple coatings, of such moving materials in the bulk container. The present invention also relates to coated materials and to uses therefore.

In accordance with one aspect of the present invention powder material is moved and mixed by the application of a mechanical force. The moving of the bed of powder in a container while the container is in a vacuum under a vapor source produced by magnetron sputtering, thermal evaporation, or other means of producing a coating vapor such as plasma enhanced chemical vapor deposition (PECVD), provides a means of coating the particles of powder with a material which will impart certain other desirable characteristics to the base material of which the powder is composed. The range of and combinations of coatings include a pure metal, co-deposited metals, and non-metals formed by reactive magnetron sputtering, evaporation or PECVD, or a sequentially deposited coating of both metals and non-metals. The method of the present invention is particularly applicable to the coating of small particles of sub-millimeter size. The particles or powder have a size of one millimeter or less. It has been found that a striking frequency in a range of 1 to 10 rpm is best for these sub-millimeter particle sizes. Larger size beads have been subject to vibration forces previously but at higher frequencies. These higher frequencies have been found to not effectively coat the particles, and may damage the particles.

Examples of applications for the method of the present invention include the manufacture of light absorbing materials such as gold coated with titanium dioxide or a base metal coated with gold and with titanium dioxide as the topcoat, rhodium or platinum catalysts wherein expensive metals like rhodium or platinum are vacuum deposited onto an inexpensive metal powder or a porous substrate of high surface area. Other possibilities include the production of graphite-coated metal particles for making self-lubricating metal components such as bearings and shafts, and the manufacture of slow dissolving coatings on pharmaceutical powders.

In accordance with one aspect of the present invention there is provided a method of moving a bed of a powdery substance which comprises placing the powdery substance into a container in a vacuum vessel. The container is moved on a platform under the vapor sources and while moving, the method includes the step of striking the container with a mechanical device to cause mixing of the bed of the powdery substance so that the powdery substance is continually moving. The striking causes a stirring of the powder bed which moves continuously under the vapor stream. In time all of the particles come in contact with the vapor and the entire surface is uniformly coated.

Reference is now made to an apparatus suitable for vacuum deposition of coating materials in accordance with a first embodiment. This apparatus is schematically illustrated in FIG. 1. This apparatus is particularly advantageous for bulk processing. The apparatus includes a vacuum chamber 1 that is connected to two vacuum pumps 2 and 3. Both of the pumps 2 and 3 are preferably valved by means of separate control valves that are not specifically shown in the drawing. Each valve may be disposed between the pump and chamber. The pump 2 is a mechanical pump which reduces pressure in the chamber 1 to on the order of 0.050 torr at which time this pump is valved off and another valve is opened to allow pump 3 to reduce pressure further into the 0.00001 torr range. The pump 3 is preferably a cryogenic vacuum pump. Argon gas and a reactive gas, if reactive magnetron sputtering is to be performed, is admitted into the vacuum chamber (such as through an appropriate gas input to the chamber) to raise the pressure in the chamber into a range on the order of 0.0005 to 0.1 torr at which time the system is in a condition to proceed with the sputter deposition process.

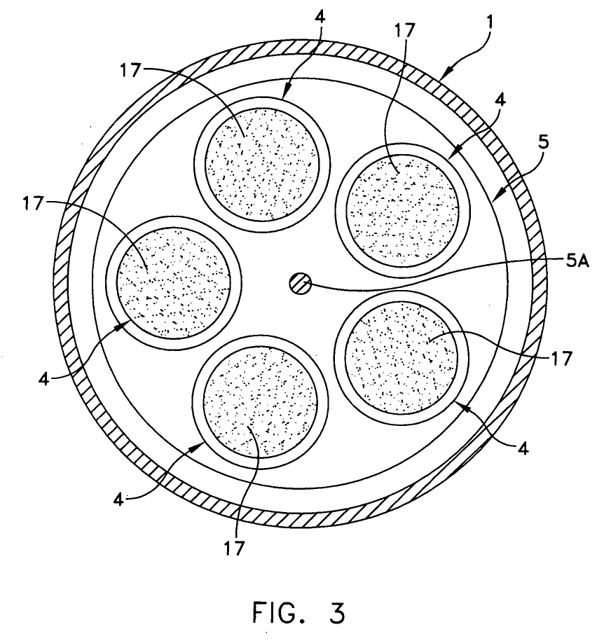

In this first embodiment of the invention, as indicated before, the powder is moved and dispersed by a striking action. In the vacuum chamber 1, several containers 4 are placed upon a rotating platform 5. The platform 5 has a series of perforations 5A on the underside of the platform 5 and is rotated by means of the rotation shaft 5B from a motor (not shown). The motor shaft 5B preferably rotates at a speed range on the order of 1 to 10 rpm. This action provides a like frequency of striking. The perforations may be disposed about a circular locus on the platform surface. In the chamber 1 shown in FIG. 1 below the platform 5 is disposed a spring loaded rod 6 that is positioned below the perforation so that the bottom of the container can be struck by rod 6 as the platform rotates. A spring 6A is positioned below the rod 6. The striking action occurs by the rod 6 successively engaging the spaced perforations as the platform 5 rotates. Refer also to FIG. 3 which is a cross-sectional view that illustrates the use of six containers 4 arranged about the platform 5.

Above the containers 4 are one or a circular array of multiple cathodes 7 which view the contents of containers 4. The cathodes 7 are charged to a high negative voltage and the ensuing plasma creates a metal vapor by argon bombardment of the target attached to the cathode. The rotating platform 5 sweeps through the metal and/or compound vapor, thus produced, and condenses on the powder which has been moved by the striking action of the rod 6 interacting with the platform 5. Each of the multiple cathodes 7 can be operated individually for sequential deposition of material or simultaneously for co-deposition of material.

In a further aspect the present invention provides a method of moving the powder in a stationary container by mechanical means with either a stirring paddle or piezo-electric transducers. The container is positioned under a multiple array of magnetron sputtering or evaporative sources and coating material is deposited on the moving bed of powder thus providing the means for sequentially coating the particles with different materials in different thicknesses or co-depositing different materials on the surface of the particle with the possibility of alternating layers of co-deposited and sequentially deposited layers of materials produced from the magnetron sputtering target, by the reaction product of the sputtered material with a reactive gas admitted to the vacuum chamber (reactive magnetron sputtering) or by the material evaporated from a thermal source. In time all of the stirred particles come in contact with the vapor and are coated.

In the second embodiment of the invention where the powder is moved continuously by stirring, reference is made to the apparatus of FIG. 2. In FIG. 2 a single stationary container 11 with a stirring paddle 12 is placed on a stationary platform 13. The stirring paddle 12 is connected via a rotary vacuum feed through 14 to a small electric motor 15. The motor shaft 16 rotates at speeds of 1 to 10 rpm. The chamber 20 may be evacuated by the same means as described in FIG. 1 including the pumps 22 and 23. The powder 17 may fill the container 11 and covers the stirring paddle 12. The powder is caused to move continuously while the motor 15 is energized. In FIG. 2 either a single paddle 12 can be used or, alternatively, more than one rotating paddle may be used to stir the powder.

A circular array of magnetron sputtering cathodes 25 is disposed above the container 20. The cathodes 25 may each contain a different target material. Each cathode has a view of the container 20 and the bed of powder 17 in the container. When the cathodes 25 are charged or excited as described previously, the deposition of the vaporized material occurs by condensing on the surface of the stirred powder 17. Since the powder is continually mixing while being stirred, all of the surfaces of the particles eventually come in contact with the vapor and are coated.

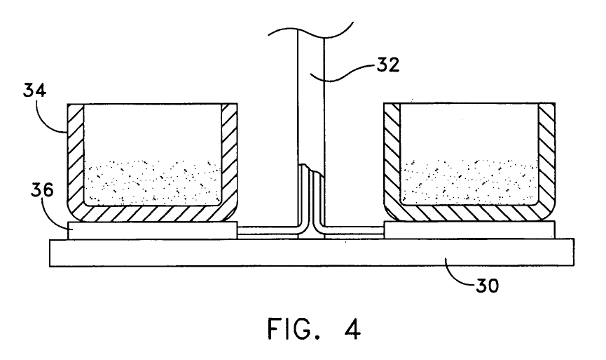

In this embodiment of the invention, instead of a paddle arrangement, several piezoelectric transducers can be used for the purpose of moving and mixing the bed of powder. In that case the piezoelectric transducers are attached directly to the container 11 for vibrating the powder within the container. In still another embodiment of the invention the magnetron sputtering cathodes 25 may be replaced by thermal evaporation sources. In a further embodiment of the invention the cathodes and evaporation sources may be replaced by a plasma generated by aluminum cathodes, in which case metal organic precursors are introduced into the chamber entrained in argon gas in a process commonly know as PECVD. A further embodiment is shown in FIG. 4 where the particulate containers are rotated. FIG. 4 is a fragmentary view of one of several containers that may be arranged in the manner shown, for example, in FIGS. 1 and 3. The container 34 is shown resting on a platform 30 that may be driven from drive shaft 32. A strip of piezo-electric material is shown supported on the platform 30 under the container 34. Particulate material is disposed in the container 34. Electric wiring can extend from the piezo-electric transducer 36 and be connected to a power source for the purpose of exciting the transducer. The transducer associated with each container may be excited at the same time and may be pulsed at a preferred frequency of 1 to 10 rpm, which will not damage the particles. Each container may include the same or different particulate material. Each of the piezoelectric transducers 36 may be one manufactured by Smart Materials Corp. of Sarasota, Fla., type I33-MFC.

In accordance with embodiments described herein the chamber vacuum is preferably in a range on the order of 0.1 to 0.0005 torr with an energized inert gas as a plasma to create the vapor (magnetron sputtering). Alternatively, the method can be carried out under conditions of a vacuum in the 0.0005 to 0.000001 torr range with a thermal source providing the means of producing the vapor (evaporative coating). A compound coating may be created by a gas that reacts with the vapor created by the energized inert gas plasma striking a charged electrode (reactive magnetron sputtering). The gas is preferably oxygen or may also be other gases known or unknown to react with the vapor that are introduced into the vacuum container to produce a compound coating material. The coating material may be vaporized from an electrode at high negative potential above an open container with a moving bed of the particulate material in a vacuum in a range on the order of 0.1 to 0.0005 torr. The coating material may be vaporized from an electrode which is at negative potential with respect to ground and the material being coated may be at ground potential, or positive potential or negative potential with respect to ground. The thickness of the coating of the vapor-coated material may be controlled by varying the rate of production of the vapor-coating material.

The magnetron sputtering process is a low temperature process and does not depend upon thermal energy to accomplish vaporization of a material. In the course of magnetron sputtering process heat is generated and the temperature of the particles will rise. This temperature rise in processing is less than 100° C., but in extended deposition cycles a further temperature rise can be limited by adding cooling apparatus to the containers.

In another aspect the present invention provides a method of moving the container holding the powder under multiple magnetron sputtering cathodes or evaporative vapor sources which contain different materials thus providing the means for sequentially coating the particles with different materials in different thicknesses or co-depositing different materials on the surface of the particle with the possibility of alternating layers of co-deposited and sequentially deposited layers of materials produced from the magnetron sputtering target, by the reaction product of the sputtered material with a reactive gas admitted to the vacuum chamber (reactive magnetron sputtering) or by the material evaporated from a thermal source. In time all of the stirred particles come in contact with the vapor and are coated.

In a further aspect, the present invention provides discrete, free-flowing coated particles having a solid inner core. By means of such coated particles it is possible to alter the surface properties of the material of the inner core including electrical properties, surface reactivity, friction (flow) characteristics, etc. For example it is possible to coat an inexpensive powder such as aluminum oxide with gold and subsequently with a layer of titanium oxide to provide free flowing particles which can be used as an additive to dye sensitized solar cells to improve their efficiency.

In accordance with the invention it is also possible to coat an inexpensive refractory metal powder (e.g. Tungsten) with a thin layer of a metal such as platinum, nickel, palladium etc., to provide free-flowing particles with a very large surface area of metal, for use as an active catalyst in, for example, hydrogenation of coal. A further variation of this would be to prepare a thin coating of metal on an inert powder (such as glass) for use as a catalyst in gas-reactions in fluidised bed reactors.

Another application for the vapor-coated powders is in the use of inter-metallic compounds for storing hydrogen. The storage of hydrogen by absorption into metal granules can be more efficient than storage of hydrogen gas under pressure (i.e. in gas cylinders). Hydrogen has a very high affinity for certain metals, with the hydrogen diffusing in between the atoms of the metals and being so retained. The hydrogen can be removed by the application of heat (e.g. by application of an electric current to the metal). To recharge the metal with hydrogen the metal is cooled and the metal is allowed to reabsorb a new supply of hydrogen. The problem is that inter-metallic compounds have a very poor thermal conductivity, and the refueling cycle (i.e. reabsorption of hydrogen) may require an unacceptable period of time (e.g. 20 minutes or more) due to the time required to cool down the intermetallic compound.

Another advantage of the apparatus and method of the present invention, is the ability to process greater amounts of particulate material. In the past only about 10 grams of material were processed per container. Now, with the present invention once can process up to 50 grams of material per container and about 900 grams in a complete batch (multiple containers). This advantage is believed to be due primarily to the improved mechanical means employed in the present invention.

According to the present invention it is possible to vapor coat intermetallic compounds (such as Iron Titanate, Magnesium alloys, etc.), in powdered or granular form, with palladium, which has a very high thermal conductivity. The coated particles are then compressed and shaped into a three-dimensional form (e.g. a bar or rod shape) wherein the palladium provides the necessary pathway for more efficient cooling of the compressed mass, to enable recharging with hydrogen. The palladium coating is also useful in that it has a high hydrogen permeability to the underlying inter-metallic compound. The palladium also serves to filter out impurities from the hydrogen gas, which impurities are found in commercial hydrogen gas, which otherwise might tend to poison the inter-metallic compound.

Other examples of use of the present invention include:
(i) Graphite-coated metal particles for the manufacture of self-lubricating metal particles, such as shafts and bearings, formed by powder-metallurgical processes;
(ii) Slow dissolving coatings on pharmaceutical powder products;
(iii) The coating of an inexpensive metal powder with a thin layer of an expensive metal such as platinum, for use as a catalyst. The coated powder can then be sintered into blocks, providing a porous three-dimensional matrix with a very extensive surface area of platinum. Such a matrix could find potential application in future fuel cell technology, providing a matrix where oxygen and hydrogen can be reacted together to generate an electric current.

### EXAMPLES

Powdered aluminum, with particles of varying sizes between −20 to +100 mesh, were coated with vacuum deposited gold at 80 degrees F. using a sputtering cathode at 600 volts DC in an Argon plasma at 0.0005 torr. The coated particles were examined visually for color and all were characteristically gold colored.

Powdered aluminum oxide with particles 300 nanometers in size were coated as described above under the same conditions as described above and the results were the same.

Powdered aluminum oxide with particles 300 nanometers is size were coated as described and immediately after the gold deposition, titanium dioxide was deposited over the gold coating. The titanium dioxide was formed by the reactive magnetron sputtering of titanium from a sputtering cathode at 0.002 torr in a gas mixture of oxygen and argon. The particles were examined visually and all of the gold coated particles had changed color.

Although the invention has been described above with reference to preferred embodiments or examples, it will be appreciated that numerous variations, modifications or alternatives may be substituted for specifically described features, without departing from the spirit or scope of the invention as broadly described.

What is claimed is:

1. A method of vapor coating of a particulate material of sub-millimeter size, comprising moving said particulate material by mechanical means and causing the movement of particulate material to interact with a vapor of a coating material.

2. A method of vapor coating of a particulate material according to claim 1, wherein said vapor coating is conducted under vacuum with said vapor of a coating material being supplied from a source internal to a vacuum chamber, and the mechanical means is activated at a frequency range on the order of 1 to 10 rpm.

3. A method of vapor coating of a particulate material according to claim 1, wherein moving of said particulate material and generation of said vapor of a coating material are conducted in a single vacuum chamber with a single or several open containers holding the particulate material of the same or different compositions.

4. A method of vapor coating of a particulate material according to claim 3 where the open container holding the particulate material is rotated under the vapor source in a sequential or random fashion.

5. A method of vapor coating of a particulate material according to claim 1, carried out under conditions of a vacuum in the 0.1 to 0.0005 torr range with an energized inert gas as a plasma to create the vapor.

6. A method of vapor coating of a particulate material according to claim 1 and carried out at a temperature of less than 100° C.

7. A method of vapor coating of a particulate material according to claim 1, carried out under conditions of a vacuum in the 0.0005 to 0.000001 torr range with a thermal source providing the means of producing the vapor.

8. A method of vapor coating of a particulate material according to claim 1, wherein a compound coating is created by a gas that reacts with the vapor created by the energized inert gas plasma striking a charged electrode.

9. A method of vapor coating of a particulate material according to claim 5, wherein said gas is oxygen or other gases known or unknown to react with the vapor are introduced into the vacuum container to produce a compound coating material.

10. A method of vapor coating of a particulate material according to claim 1, wherein said coating material is vaporized from an electrode at high negative potential above an open container with a moving bed of said particulate material in a vacuum in the range 0.1 to 0.0005 torr.

11. A method of vapor coating of a particulate material according to claim 1, wherein said coating material is vaporized from an electrode which is at negative potential with respect to ground and said material being coated is at ground potential, or positive potential or negative potential with respect to ground.

12. A method of vapor coating of a particulate material according to claim 1, including moving the particulate material at a frequency on the order of 1 to 10 rpm for sub-millimeter particle sizes.

13. A method of vapor coating of a particulate material according to claim 1, wherein the thickness of the coating of the vapor-coated material is controlled by varying the rate of production of said vapor-coating material.

14. A method of vapor coating of a particulate material according to claim 1 wherein the moving of the particulate material is by striking the container for the particulate material.

15. A method of vapor coating of a particulate material according to claim 1 wherein the moving of the particulate material is by stirring the material in the container for the particulate material.

16. A method of preparing discrete coated particles having:
(i) an inner core of a first material which is capable of being moved by a mechanical means.
(ii) an outer coating of a second material which is capable of being vaporized, said method comprising:
a) moving particles of said first material by the application of a mechanical force at a frequency on the order of 1 to 10 rpm; and
(b) vaporizing of and subsequently depositing said second material as a vapor onto the surface of said particles of the first material while said particles are moved.
(iii) subsequent coatings of the same materials or other materials can be added according to the preceding scheme by incorporating sufficient magnetron sputtering electrodes and charging them sequentially or simultaneously.

17. An apparatus for coating sub-millimeter size particulate material in a vacuum chamber, comprising:
a container for the sub-millimeter size particulate material;
means for supporting the container in the chamber;
means for mechanically agitating the particulate material within the container; and
electrode means for establishing a coating vapor within the vacuum chamber.

18. An apparatus according to claim 17 including a platform for the container, including a plurality of containers on the platform, said mechanical means including a strike rod engaging with the platform for mechanically moving the particulate material at a frequency on the order of 1 to 10 rpm.

19. An apparatus according to claim 17 including a platform for the container, including a plurality of containers on the platform, said mechanical means including a piezoelectric transducer engaging with the platform for mechanically moving the particulate material at a frequency such that the particles are not damaged.

20. An apparatus according to claim 17 including a platform for the container, said mechanical means including a stirring paddle for stirring the particulate material in the container, said container maintained stationary.
